(19) United States
(12) Patent Application Publication
(10) Pub. No.: US 2026/0338229 A1
(43) Pub. Date: Oct. 29, 2026

(54) APPARATUS FOR REDUCING VIBRATIONS IN AN AIR CUSHION MOTION CONTROL SYSTEM

(71) Applicant: MICRO-CONTROLE-SPECTRA PHYSICS, Evry-Courcouronnes (FR)

(72) Inventor: Eric Durand, Evry-Courcouronnes (FR)

(73) Assignee: MICRO-CONTROLE-SPECTRA PHYSICS, Evry-Courcouronnes (FR)

(21) Appl. No.: 19/107,069

(22) PCT Filed: Sep. 1, 2023
(86) PCT No.: PCT/EP2023/074010

§ 371 Date: Feb. 27, 2025

(30) Foreign Application Priority Data
Sep. 16, 2022 (FR) FR2209361

(51) Int. Cl. F16C 32/06; H10P 72/30

(52) U.S. Cl. CPC F16C 32/0622; H10P 72/36

(57) ABSTRACT

The present application discloses embodiments of an air bearing assembly. In one embodiment, the air bearing assembly comprises at least one base having at least one base air bearing surface, at least one carriage having at least one carriage body with at least one pressure air bearing surface formed therein, at least one fluid fitting assembly positioned in the carriage body and in fluid communication with at least one positive air pressure source via at least one conduit, the fluid fitting assembly configured to provide air pressure and flow from the positive air pressure source to the at least one pressure air bearing surface to create an air cushion. The at least one fluid fitting assembly includes at least one flow control nozzle and at least one diffusing element positioned downstream of the at least one flow control nozzle.

### TECHNICAL BACKGROUND

Air bearing assemblies are used for a variety of applications, including positioning systems for semiconductor wafers. In some applications, very high stability of the semiconductor wafer carried by air bearing carriages is required. In particular, vibration of the semiconductor wafer must be minimized. While prior art air bearing assemblies have proven useful in the past, a number of shortcomings have been identified. For example, the air flow fittings that provide positive air pressure to air bearing surfaces can cause unacceptable levels of vibration of the air bearing carriage. In light of the foregoing, there is an ongoing need for an improved design for such air flow nozzles and fittings.

### SUMMARY OF THE INVENTION

The present application discloses various embodiments of a an air bearing assembly. In one embodiment, the air bearing assembly comprising at least one base having at least one base air bearing surface, at least one carriage having at least one carriage body with at least one pressure air bearing surface formed therein, at least one fluid fitting assembly positioned in the carriage body and in fluid communication with at least one positive air pressure source via at least one conduit, wherein the at least one fluid fitting assembly configured to provide air pressure and air flow from the positive air pressure source to the at least one pressure air bearing surface thereby creating an air cushion between the at least one pressure air bearing surface and the at least one base air bearing surface. The at least one fluid fitting assembly includes at least one flow control nozzle and at least one diffusing element positioned downstream of the at least one flow control nozzle.

The fluid fitting assembly further comprises at least one fitting body and at least one flow control nozzle. The at least one diffusing element is configured to reduce a turbulence in the air cushion formed between the at least one pressure air bearing surface and the at least one base air bearing surface. The diffusing element effectively reduces the vibration of the carriage of the air bearing assembly.

The material of the diffusing element is selected from a group consisting of particle filter materials, plastic fibers, glass fibers, micro-glass, porous ceramics, cellular ceramics, synthetic porous materials, aerogels, foam ceramics, open-cell plastic foams, sintered polymers, sintered metals, and metallic filter materials.

The invention, according to at least one of its embodiments also concerns an air bearing assembly, comprising: at least one base having at least one base air bearing surface; at least one carriage having at least one carriage body with at least one pressure air bearing surface formed therein; at least one fluid fitting assembly positioned in the carriage body and in fluid communication with at least one positive air pressure source via at least one conduit, the at least one fluid fitting assembly configured to provide air pressure and flow from the positive air pressure source to the at least one pressure air bearing surface to create an air cushion between the at least one pressure air bearing surface and the at least one base air bearing surface; wherein the at least one fluid fitting assembly includes at least one flow control nozzle and at least one diffusing element positioned downstream of the at least one flow control nozzle.

According to at least one embodiment of the present invention, the fluid fitting assembly further comprises at least one fitting body, and at least one flow control nozzle.

According to at least one embodiment of the present invention, the at least one diffusing element is configured to reduce a turbulence in at least one air cushion formed between the at least one pressure air bearing surface and the at least one base air bearing surface.

According to at least one embodiment of the present invention, the at least one diffusing element is configured to reduce at least one vibration of the at least one carriage.

According to at least one embodiment of the present invention, the material of the diffusing element is selected from a group consisting of particle filter materials, plastic fibers, glass fibers, micro-glass, porous ceramics, cellular ceramics, synthetic porous materials, aerogels, foam ceramics, open-cell plastic foams, sintered polymers, sintered metals, and metallic filter materials.

The invention according to at least one of its embodiments also concerns a fluid fitting assembly, comprising: at least one fitting body having at least one fluid inlet port in communication with at least one positive fluid pressure source, and configured to allow the flow of a fluid therethrough, wherein the at least one fitting body includes at least one first volume downstream of the at least one fluid inlet port; at least one flow control nozzle positioned downstream of the at least one first volume; at least one diffusing element having at least one fluid outlet port, the at least one diffusing element positioned downstream of the at least one flow control nozzle, wherein the at least one diffusing element is configured to accept a flow of fluid from the at least one positive fluid pressure source and distribute the flow of fluid across a transverse dimension of the at least one fluid outlet port.

According to at least one embodiment of the present invention, the material of the diffusing element is selected from a group consisting of particle filter materials, plastic fibers, glass fibers, micro-glass, porous ceramics, cellular ceramics, synthetic porous materials, aerogels, foam ceramics, open-cell plastic foams, sintered polymers, sintered metals, and metallic filter materials.

### BRIEF DESCRIPTION OF THE DRAWINGS

Various embodiments of an improved air bearing assembly will be explained in more detail by way of the accompanying drawings, wherein:

FIG. 1 shows a perspective view of an embodiment of an air bearing assembly;

FIG. 2 shows an underneath perspective view of the embodiment of an air bearing carriage shown in FIG. 1;

FIG. 3 shows a close-up view of the embodiment of an air bearing carriage shown in FIG. 2;

FIG. 4 shows a partial cross-section view of the embodiment off the air bearing assembly shown in FIG. 1;

FIG. 5 shows a cross-section view of an embodiment of air pressure fitting configured to supply air pressure to the air bearing assembly shown in FIG. 1.

FIG. 6 shows an exemplary simulation of air flow through a nozzle region of the air pressure fitting shown in FIG. 5;

FIG. 7 shows a cross-section view of an exemplary embodiment of an improved air pressure fitting configured to supply air pressure to the air bearing assembly shown in FIG. 1;

FIG. 8 shows a view of an exemplary embodiment of a prototype air bearing carriage;

FIG. 9 shows a close-up view of the exemplary embodiment of the prototype air bearing carriage shown in FIG. 8.

### DETAILED DESCRIPTION OF THE INVENTION

Example embodiments are described herein with reference to the accompanying drawings. Unless otherwise expressly stated, in the drawings the sizes, positions, etc., of components, features, elements, etc., as well as any distances therebetween, are not necessarily to scale, and may be exaggerated for clarity. In the drawings, like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

The terminology used herein is for the purpose of describing particular exemplary embodiments only and is not intended to be limiting. Unless otherwise defined, all terms (including technical and scientific terms) used herein have the same meaning as commonly understood by one of ordinary skill in the art. The terms “at least one”, “at least a”, and “one or more” may are intended to include both the singular and plural forms, depending on the context. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless indicated otherwise, terms such as “first,” “second,” etc., are only used to distinguish one element from another. For example, one coupler could be termed a “first coupler” and similarly, another coupler could be termed a “second coupler”, or vice versa.

Unless indicated otherwise, spatially relative terms, such as “below,” “beneath,” “lower,” “above,” and “upper,” “opposing,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly. A set of reference axes (e.g., X, Y, Z), directions, or coordinates, and the rotation around them (e.g., θx, θY, θZ) may be included in the FIGS. for the purpose of orienting the reader to facilitate understanding of the FIGS. and the specification, and do not necessarily indicate that any particular feature or element is aligned with, or is orthogonal to, any other feature or element.

The paragraph numbers used herein are for organizational purposes only, and, unless explicitly stated otherwise, are not to be construed as limiting the subject matter described. It will be appreciated that many different forms, embodiments and combinations are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

The term “air bearing” throughout this disclosure may be used generically, and it will be appreciated that any variety of gasses or other fluids may be used therewith. As such, the terms “fluid pressure”, “positive pressure”, or “positive fluid pressure” can be construed to denote positive pressure of air, carbon dioxide, nitrogen, inert gasses, and the like, or liquids such as water, oils and the like.

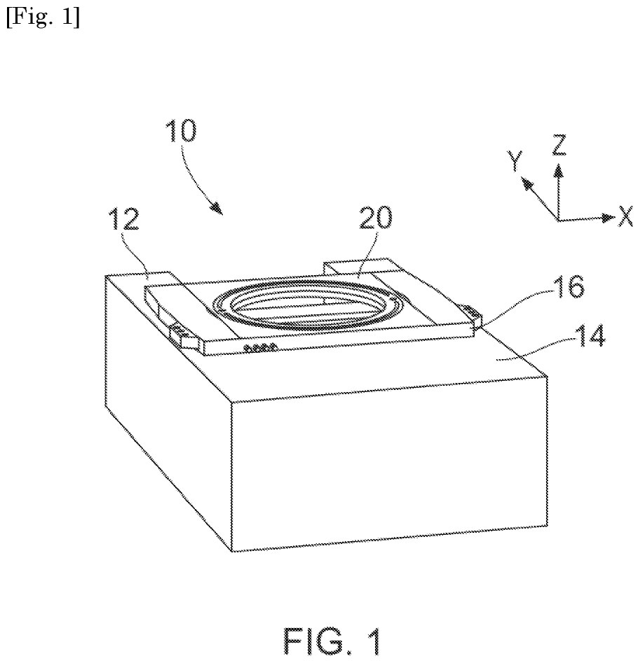

FIG. 1 show a perspective view of an exemplary embodiment of an air bearing assembly 10. The air bearing assembly 10 includes a base 12 having an base air bearing surface 14 (i.e., a reference plane on which an air bearing carriage 20 will “fly” on a cushion of air). In the illustrated embodiment, the base 12 is formed from a ceramic material such as silicon carbide, or any one of a number other ceramic materials. In other embodiments, the base 12 may be made from granite, steel, aluminum or any of a variety of materials. The air bearing carriage 20 (also referred to herein as the carriage”) moves relative to the base 12 in the X- and Y-directions on one or more air cushions 16 (e.g., created between the pressure air bearing surface 24 and the base air bearing surface 14) that support the carriage 20 in the Z direction. In this embodiment, the carriage 20 is moved in the X- and Y-directions by one or more linear motors (not shown). The carriage 20 is configured to support and secure a payload, including a variety of devices. In the illustrated embodiment, the payload is a wafer chuck (not shown) that holds a semiconductor wafer (also referred to herein as a “wafer”) during wafer processing steps (e.g., deposition, etch, inspection, etc.). Those skilled in the art will appreciate that the payload may include a wide variety of objects.

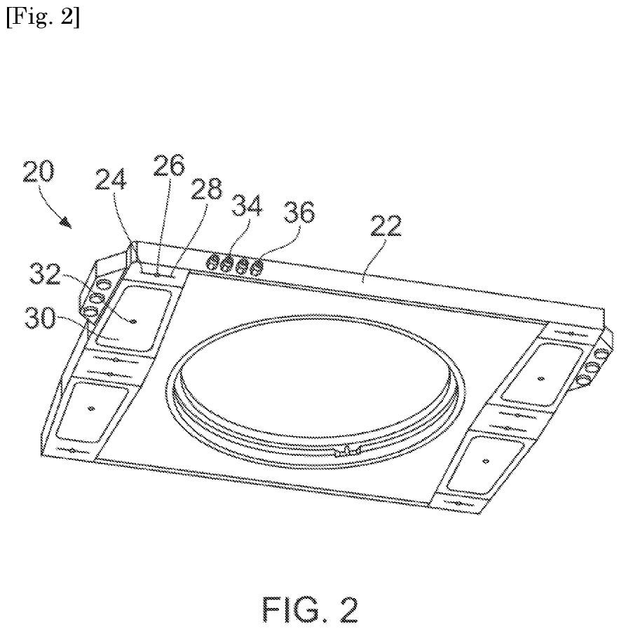

FIG. 2 shows a perspective view of the underneath of the carriage 20. The carriage 20 includes at least one carriage body 22. In the illustrated embodiment, the carriage body 22 is formed from a ceramic material such as silicon carbide or any one of a number other ceramic materials. In other embodiments, the carriage body 22 may be made from granite, steel, aluminum or any of a variety of materials. One or more pressure air bearing surfaces 24 (also referred to herein as “pressure areas”) and one or more vacuum air bearing surfaces 30 (also referred to herein as “vacuum areas”) are formed in the carriage body 22. In the illustrated embodiment, the carriage body 22 has six pressure air bearing surfaces 24 and four vacuum air bearing surfaces 30. Those skilled in the art will appreciate that the carriage body 22 may have any number of pressure air bearing surfaces 24 and vacuum air bearing surfaces 30 formed therein. The pressure air bearing surface 24 includes at least one orifice 26 (also referred to herein as a “pressure orifice 26”) in fluid communication with at least one positive air pressure and air flow source (not shown) that is controlled by one or more pneumatic controllers. The pressure source is connected to the carriage 20 by one or more fluid pressure inlets 34. The pressure orifice 26 is configured to transmit sufficient positive air pressure and air flow from the positive air pressure source to the pressure air bearing surface 24 sufficient to create the air cushion 16 between the pressure air bearing surfaces 24 and the base air bearing surface 14 that allows the carriage 20 to move in the X- and Y-directions relative to the base 12. In the illustrated embodiment, each pressure air bearing surface 24 has a single pressure orifice 26 formed therein. In other embodiments, the pressure air bearing surface 24 may have multiple pressure orifices 26 formed therein. In one embodiment, the pressure orifice 26 may be provided as a single hole formed in the ceramic material of the carriage body 22 in the pressure air bearing surface 24. In other embodiments, the pressure orifice 26 may be provided as an fluid fitting assembly (such as the fluid fitting assemblies 50 and 100 described below) that are configured to precisely control the air pressure and air flow from the positive fluid pressure source to the pressure air bearing surface 24. One or more channels 28 may be formed in the pressure air bearing surface 24, the channels 28 being configured to facilitate the distribution or air from the pressure orifice 26 across the pressure air bearing surface 24. The vacuum air bearing surfaces 30 include one or more vacuum orifices 32 that are in fluid communication with at least one negative air pressure source (also referred to herein as a “vacuum source” (not shown)) that is controlled one or more of the pneumatic controllers described above. The vacuum source is connected to the carriage 20 by one or more vacuum inlets 36. The vacuum air bearing surfaces 30 are configured to clamp the carriage 20 to the base air bearing surface 14 when the wafer is required to be stationary relative to the base 12 (e.g., during process steps performed during wafer fabrication), by shutting off (e.g., in response to control commands from the pneumatic controller) the positive air pressure to the pressure air bearing surfaces 24 and applying a vacuum to the vacuum air bearing surfaces 30 through the vacuum orifice 32.

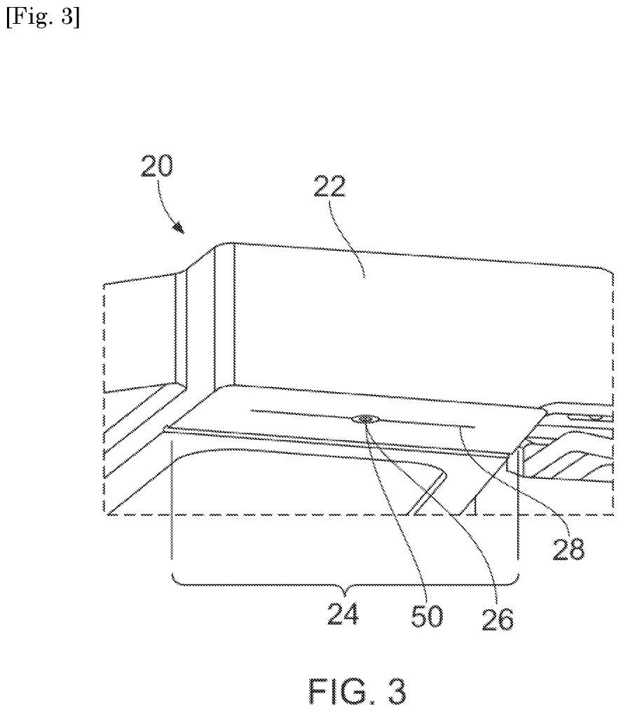

FIG. 3 shows a close-up view one of the pressure air bearing surfaces 24 of the carriage 20 having the pressure orifice 26 and channel 28 formed in the carriage body 22. In some embodiments, the pressure orifice 26 is provided as an fluid fitting assembly 50 configured to control the flow of air to the pressure air bearing surface 24 (e.g., to control the flow and pressure of the air in the air cushion 16).

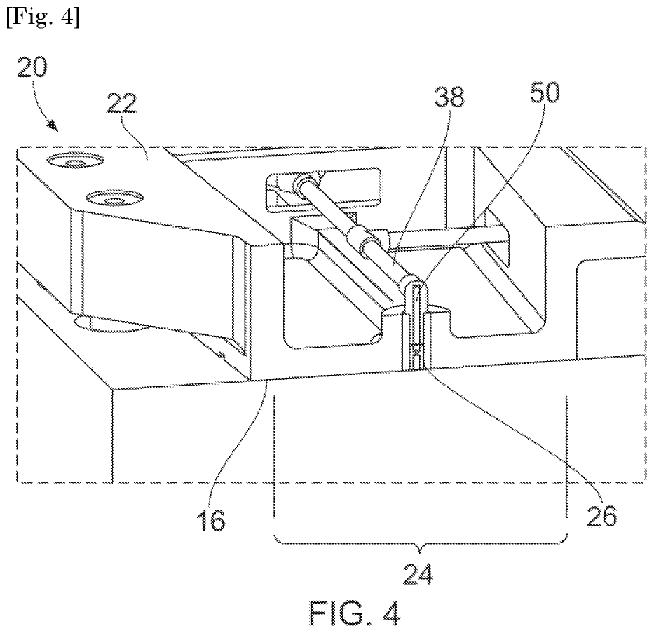

FIG. 4 shows a section view of the pressure air bearing surface 24. The fluid fitting assembly 50 is in fluid communication with the positive air pressure source via a conduit 38. The air flows through the conduit 38 to the pressure air bearing surface 24 through an exemplary fluid fitting assembly 50 to create the air cushion 16.

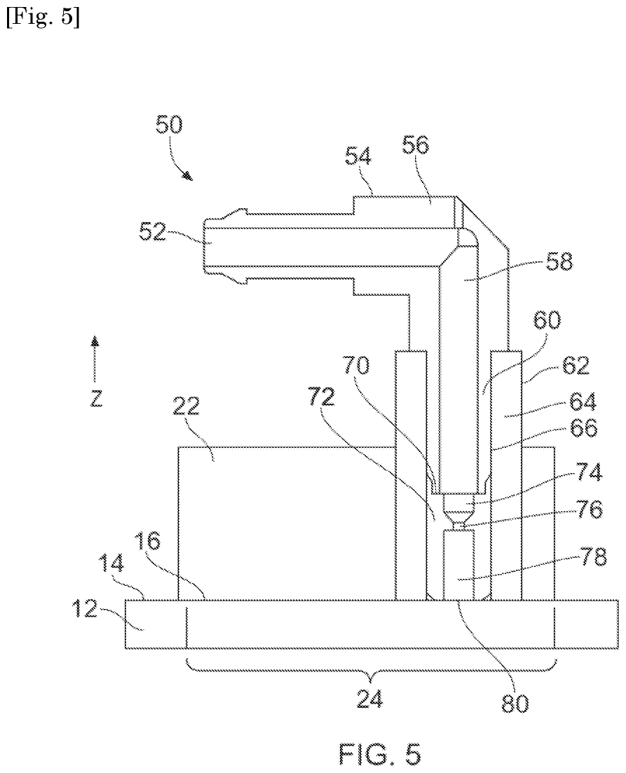

FIG. 5 shows a section view of an exemplary embodiment of the fluid fitting assembly 50 configured to control the flow of air to the pressure air bearing surface 24 to maintain the air cushion 16 between the base air bearing surface 14 and the carriage 20. In the illustrated embodiment, the fluid fitting assembly 50 includes a fitting 54, a bushing 62, and a flow control nozzle 70. The bushing 62 includes a bushing body 64 with at least one passage 66 formed therein. The fitting 54 includes an upper fitting body 56 and a lower fitting body 60, with an upper volume 58 formed therein. In this embodiment, the upper fitting body 56 and the lower fitting body 60 are formed monolithically, though those skilled in the art will appreciate that upper fitting body 56 and the lower fitting body 60 may be separate parts. In the illustrated embodiment, the bushing 62 is press-fit into a passage formed in the carriage body 22, and the lower fitting body 60 is pressed into the passage 64 formed in the bushing body 64. Collectively, the upper fitting body 56, the lower fitting body 60, and the bushing 62 may also be referred to herein as the “fitting body”.

At least one fluid inlet port 52 in fluid communication with the positive air pressure source is formed in the upper fitting body 56. The flow control nozzle 70 is positioned downstream of the fluid inlet port 52. In the illustrated embodiment, the flow control nozzle 70 is a separate part from the fitting 54. Alternatively, the flow control nozzle 70 can be formed monolithically with the fitting 54. The flow control nozzle 70 includes at least one nozzle body 72 having at least one upper chamber 74, at least one orifice 76, and at least one lower chamber 78 and a fluid outlet port 80 formed therein. Alternatively, the flow control nozzle 70 may not include an upper chamber 74 and a lower chamber 78, instead having only a single passage having a constant diameter extending through the nozzle body 72. In another embodiment, the single passage through the nozzle body 72 may have a taper. The orifice 76 is configured to control the air flow from the upper chamber 74 to the lower chamber 78, and out of the fluid outlet port 80. Specifically, the orifice 76 is sized to allow a specific amount of fluid (e.g., based on a calibration performed a priori) to flow therethrough, depending on the available pressure and flow from the aforementioned fluid pressure source. During operation of the air bearing assembly 10, a flow of air enters the fluid inlet port 52, into the upper volume 58, into the upper chamber 74 of the flow control nozzle 70, through the orifice 76, into the lower chamber 78 and exits the fluid outlet port 80 into the pressure air bearing surface 24 to create the air cushion 16 between the carriage body 22 and the base air bearing surface 14 of the base 12.

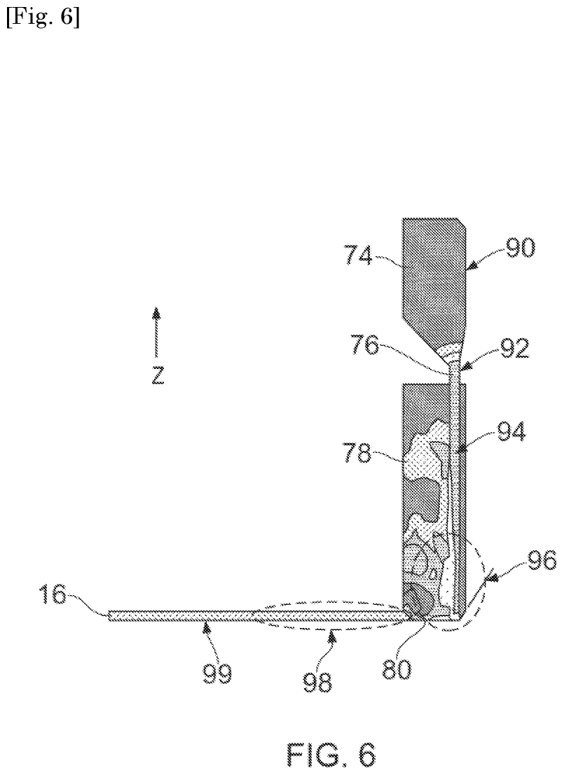

FIG. 6 shows a view of an exemplary simulation of the air flow through the flow control nozzle 70. The simulation is configured to show areas of turbulence of the air flow through different regions in the flow control nozzle 70 and the air cushion 16. The simulation assumes that the mass of the air flowing through the regions of the flow control nozzle is constant. For the purposes of the description below, definitions of the following terms are provided. The terms “flow density” or “fluence” refer to the amount of air flowing through a particular area transverse (a cross-section of the region) to the flow direction. For example, for a given flowing mass of air, because the transverse area of the upper chamber 74 is large relative to the transverse area of the orifice 76, the “flow density” or “fluence” of the air flow is lower in the upper chamber 74 and faster in the orifice 76.

The simulation shows the flow of air from the upper chamber 74, through the orifice 76, into the lower chamber 78, and out of the fluid outlet 80 into the air cushion 16.

The simulation includes an upper flow region 90 in the upper chamber 74, a orifice region 92 in the orifice 76, and lower flow regions 94 and 96 in the lower chamber 78. Flow regions 98 and 99 are located within the air cushion 16. The darker areas shown in the simulation indicate that the fluence is relatively low. The air flow in the upper flow region 90 is relatively slow. The fluence of air in the in the nozzle region 92 is higher than in the other regions, due to the restriction of the orifice 76. As the air exits the orifice 76 and enters the lower chamber 78, it stays organized for a certain length through the flow region 94. The flow becomes turbulent in the lower flow region 96 (also referred to herein as the “first turbulent flow region 96”) and the turbulence persists after the fluid leaves the outlet port 80 and enters the flow region 98 (also referred to herein as the “second turbulent flow region 98”). The turbulence dissipates as the flow reaches further into the air cushion 16, such as in the flow region 99. Those skilled in the art will appreciate that the simulation shown in FIG. 6 is only one of many examples of flow through the flow control nozzle 70, and should not be considered limiting. For example, higher or lower mass flow rates through the flow control nozzle 70 would result in different levels of turbulence in all of the flow regions 90, 92, 94, 98, and 99.

The turbulent flow in the turbulent regions 96, 98, and any residual turbulence in region 99 can cause or allow the carriage body 22 (or regions of the carriage body 22) to undergo rapid oscillation or motion (i.e., vibration, also referred to herein as “jitter”) in the Z-direction either when the carriage 20 is static, or during motion of the carriage 20 in the X- or Y-directions. The jitter of the carriage 20 may also induce vibrations or affect the vibrational state of the carriage body 22 in the X- and/or Y-directions as well. Any or all of this jitter may be transmitted from the carriage 20 to the chuck support, the wafer chuck, and eventually to the semiconductor wafer being processed. In one embodiment, the amplitude of the jitter is ±15 nanometers or less. In another embodiment, the amplitude of the jitter is ±10 nanometers or less. In another embodiment, the amplitude of the jitter is ±5 nanometers or less. In another embodiment, the amplitude of the jitter is ±2 nanometers or less. Those skilled in the art will appreciate that the amplitude of the jitter may be any amount. The frequency of the jitter may vary widely.

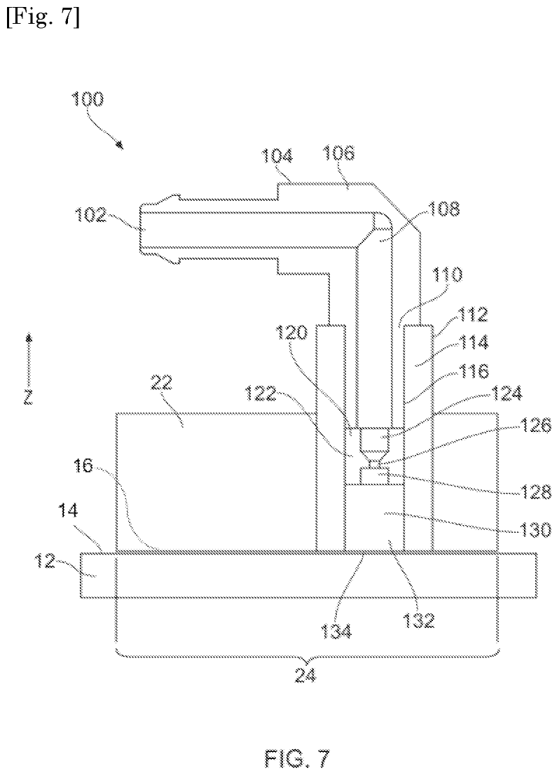

FIG. 7 shows a section view of an exemplary embodiment of an fluid fitting assembly 100 configured to control the flow of air to the pressure air bearing surface 24 to maintain the air cushion 16. In the illustrated embodiment, the fluid fitting assembly 100 includes a fitting 104, a bushing 112, a flow control nozzle 120 (also referred to herein as “nozzle 120”), and a diffusing element 130. The fitting 104 includes an upper fitting body 106 and a lower fitting body 110, with an upper volume 108 formed therein. In this embodiment, the upper fitting body 106 and the lower fitting body 110 are formed monolithically, though those skilled in the art will appreciate that upper fitting body 106 and the lower fitting body 110 may be separate parts. At least one fluid inlet port 102 in fluid communication with the air pressure source (not shown) is formed in the upper fitting body 106. The upper volume 108 is positioned downstream of the fluid inlet port 102. In the illustrated embodiment, the fitting 104 has an “elbow” configuration, though those skilled in the art will appreciate that the fitting 104 may have a straight configuration. The lower fitting body 110 is pressed into a passage 116 formed in a bushing body 114 of the bushing 112. The bushing 112 is press-fit into the carriage body 22. The flow control nozzle 120 is positioned downstream of the fluid inlet port 102 and the upper volume 108. In the illustrated embodiment, the flow control nozzle 120 is a separate part from the fitting 104.

Alternatively, the flow control nozzle 120 can be formed monolithically with the fitting 104. The flow control nozzle 120 includes a nozzle body 122 having an upper chamber 124, a orifice 126, and a lower chamber 128. The orifice 126 is configured to control the air flow from the upper chamber 124 and the lower chamber 128. In the illustrated embodiment, a diffusing element 130 having a diffusing element body 132 is positioned in the passage 116 between the lower chamber 128 and the air cushion 16, downstream of the fluid inlet port 102 and the upper volume 108.

During operation of the air bearing assembly 10, a flow of air enters the fluid inlet port 102 from the positive air pressure source, into the upper volume 108, into the upper chamber 124 of the flow control nozzle 120, through the orifice 126, into the lower chamber 128 and into the diffusing element 130, then exits the fluid outlet port 134 into the air cushion 16 between the pressure air bearing surface 24 and the base air bearing surface 14 of the base 12. The diffusing element 130 is configured to accept the flow of air from the lower chamber 128 and spread the air flow (e.g., relatively homogenously) over the entire diameter of the fluid outlet port 134, thereby reducing the turbulence of the air flow from the fluid outlet port 134 into the air cushion 16, and reducing the oscillation, vibration or jitter of the air bearing carriage Exemplary materials used for the diffusing element body 132 include, without limitation, materials used in particle filters (such as plastic fibers or microglass), porous ceramics (porous grain ceramics (e.g., with micropores or mesopores)), cellular ceramics, synthetic porous materials such as “aerogels”, foam ceramics, open-cell plastic foams, sintered polymers, sintered metals, and metallic filter materials (e.g., steel wool). Those skilled in the art will appreciate that a wide variety of materials may form the diffusing element body 132. In the illustrated embodiment, the diffusing element body 132 has a porosity of 10 microns or less. In another embodiment, the diffusing element body 132 has a porosity of 5 microns or less. In another embodiment, the diffusing element body 132 has a porosity of 2 microns or less. In another embodiment, the diffusing element body 132 has a porosity of less than 1 micron. Those skilled in the art will appreciate that the diffusing element body 132 may have any porosity. The diffusing element 130 may be secured in the passage 116 in any of a variety of ways. The diffusing element 130 may be bonded to the passage 116 by adhesives (e.g., epoxies, cyanoacrylate adhesives or the like, without limitation). The diffusing element 130 may also be retained in the passage 116 mechanically (e.g., by press-fitting, threading, or retention by one or more fasteners). In another embodiment, the diffusing element body 132 may be permanently attached to the flow control nozzle 120. In some embodiments, the flow control nozzle 120 may not be required. The diffusing element 130 may perform the flow regulation functions of the flow control nozzle 120 by itself. In still other embodiments, at least some of the internal features of the flow control nozzle 70 may instead be formed in the diffusing element body 132.

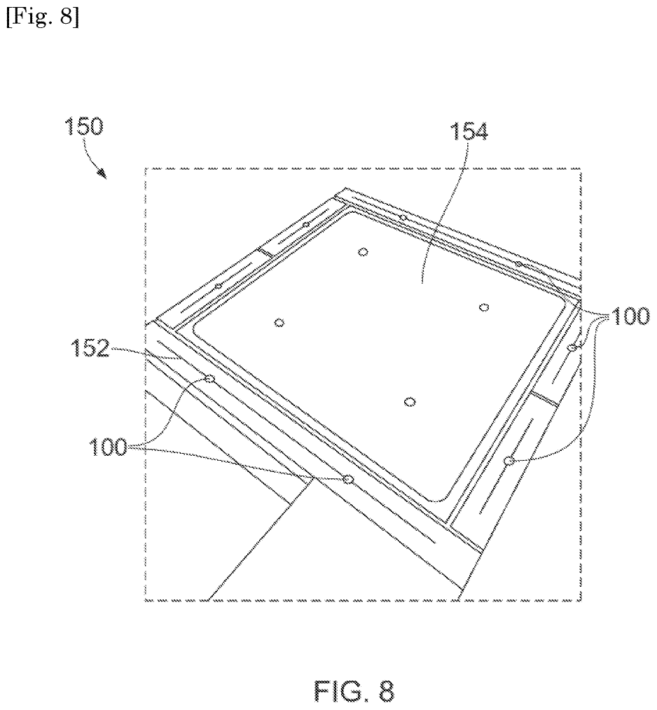

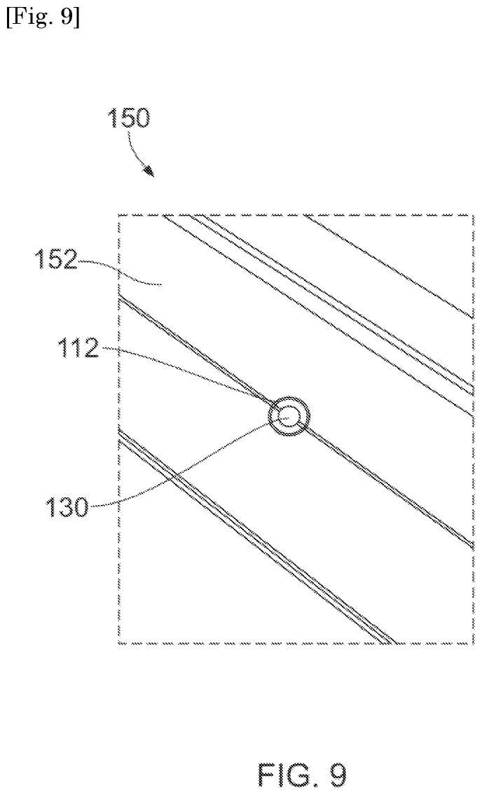

FIG. 8 shows a underside view of an exemplary prototype air bearing carriage 150 having one or more pressure air bearing surfaces 152 and at least one vacuum air bearing surface 154. Multiple air fitting assemblies 100 are installed in the pressure air bearing surfaces 152. FIG. 9 shows a close-up view of the prototype air bearing carriage 150, showing the bushing 112 and the diffusing element 130 positioned in the pressure air bearing surface 152.

The embodiments described above are illustrative of air bearing arrangements with air bearing carriages having improved air fitting assemblies configured to reduce the turbulence in the air cushions, thereby potentially reducing oscillation, vibration and jitter of the air bearing carriages. Those skilled in the art will appreciate that the air bearing configurations described above may be expanded to any number of air bearing systems, without departing from the spirit of the foregoing disclosure.

The foregoing is illustrative of embodiments and examples of the invention, and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications to the subject matter described herein are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

### LIST OF REFERENCE SIGNS

10 Air bearing assembly
12 Base
14 Surface
16 Air cushion
20 Carriage
22 Carriage body
24 Pressure air bearing surface
26 Pressure orifice
28 Channel
30 Vacuum air bearing surface
32 Vacuum orifice
34 Fluid pressure inlet
36 Vacuum inlet
38 Conduit
50 Fluid fitting assembly
52 Fluid inlet port
54 Fitting
56 Upper fitting body
58 Upper volume
60 Lower fitting body
62 Bushing
64 Bushing body
66 Passage
70 Flow control nozzle
72 Nozzle body
74 Upper chamber
76 Orifice
78 Lower chamber
80 Fluid outlet port
90 Upper volume
92 Orifice region
94 Flow region
96 Flow region
98 Flow region
99 Flow region
100 Fluid fitting assembly
102 Fluid inlet port
104 Fitting
106 Upper fitting body
108 Upper volume
110 Lower fitting body
112 Bushing
114 Bushing body
116 Passage
120 Flow control nozzle
122 Nozzle body
124 Upper chamber
126 Orifice
128 Lower chamber
130 Diffusing element
132 Diffusing element body
134 Fluid outlet port
150 Prototype carriage
152 Air bearing pad
154 Vacuum pad

1. A fluid fitting assembly, comprising:
at least one fitting body having at least one fluid inlet port in communication with at least one positive fluid pressure source, and configured to allow a flow of a fluid therethrough, wherein the at least one fitting body includes at least one first volume downstream of the at least one fluid inlet port;
at least one flow control nozzle positioned downstream of the at least one first volume, wherein the at least one flow control nozzle comprises at least a nozzle body having at least an upper chamber, at least an orifice, and at least a lower chamber;
at least one diffusing element positioned downstream of the at least one flow control nozzle and upstream of at least one fluid outlet port, wherein the at least one diffusing element is configured to accept the flow of a fluid from the at least one positive fluid pressure source and distribute the flow of a fluid across a transverse dimension of the at least one fluid outlet port.

2. The fluid fitting assembly of claim 1, wherein the material of the at least one diffusing element is selected from a group consisting of particle filter materials, plastic fibers, glass fibers, micro-glass, porous ceramics, cellular ceramics, synthetic porous materials, aerogels, foam ceramics, open-cell plastic foams, sintered polymers, sintered metals, and metallic filter materials.

3. The fluid fitting assembly of claim 1, further comprising a bushing body having a passage formed therein, wherein the at least one fitting body is pressed into the passage.

4. (canceled)

5. (canceled)

6. (canceled)

7. (canceled)

8. An air bearing assembly, comprising:
at least one base having at least one base air bearing surface;
at least one carriage having at least one carriage body with at least one pressure air bearing surface formed therein; and
a fluid fitting assembly positioned in the at least one carriage body, the fluid fitting assembly comprising:
at least one fitting body having at least one fluid inlet port in fluid communication with a positive fluid pressure source, and configured to allow a flow of a fluid therethrough;
at least one flow control nozzle positioned downstream of the at least one fluid inlet port, wherein the at least one flow control nozzle includes at least one orifice;
at least one diffusing element positioned downstream of the at least one flow control nozzle and upstream of at least one fluid outlet port, wherein the at least one diffusing element is configured to accept the flow of a fluid from the positive fluid pressure source and distribute the flow of a fluid across a transverse dimension of the at least one fluid outlet port.

9. The air bearing assembly of claim 8, wherein the material of the at least one diffusing element is selected from a group consisting of particle filter materials, plastic fibers, glass fibers, micro-glass, porous ceramics, cellular ceramics, synthetic porous materials, aerogels, foam ceramics, open-cell plastic foams, sintered polymers, sintered metals, and metallic filter materials.

10. The air bearing assembly of claim 8, further comprising a bushing body having a passage formed therein, wherein the fitting body is pressed into the passage.
